(19) United States
(12) Patent Application Publication
(10) Pub. No.: US 2024/0243077 A1
(43) Pub. Date: Jul. 18, 2024

(54) APPARATUS INCLUDING AIR GAP IN SCRIBE REGION OF SEMICONDUCTOR DEVICE

(71) Applicant: MICRON TECHNOLOGY, INC., BOISE, ID (US)

(72) Inventor: Shigeru Sugioka, Higashihiroshima (JP)

(73) Assignee: MICRON TECHNOLOGY, INC., Boise, ID (US)

(21) Appl. No.: 18/521,264

(22) Filed: Nov. 28, 2023

Related U.S. Application Data
(60) Provisional application No. 63/479,961, filed on Jan. 13, 2023.

(51) Int. Cl. H01L 23/00; H01L 23/31; H01L 23/58

(52) U.S. Cl. CPC H01L 23/562; H01L 23/3192; H01L 23/585

(57) ABSTRACT

According to one or more embodiments, an apparatus includes an insulating structure in the scribe region, a plurality of metal layers, the metal layers including a top metal layer in the insulating structure in the scribe region, a groove on a top of the insulating structure in the scribe region, and an air gap between the top metal layer and the groove in the scribe region.

### CROSS REFERENCE TO RELATED APPLICATION(S)

This application claims priority to U.S. Provisional Application No. 63/479,961, filed Jan. 13, 2023. The aforementioned application is incorporated herein by reference, in its entirety, for any purpose.

### BACKGROUND

High data reliability, high speed of memory access, lower power consumption and reduced chip size are features that are demanded from semiconductor memory. Some semiconductor devices include a low-k film of an insulating material, such as silicon oxycarbide (SiOC) and silicon carbonitride (SiCN), having a low dielectric constant (k) that exhibits weak electric polarization between conductive layers. Such insulating material is also referred to as a low-k material. The low-k film reduces parasitic capacitance between the conductive layers to achieve high-speed operations of electronic circuits in the semiconductor devices.

However, since the low-k material has weak thermo-mechanical characteristics, adhesion of the low-k film to its adjacent conductive layer or conductive components, such as interconnects, is weaker or lower compared to a silicon dioxide (SiO₂) film and a silicon nitride (Si₃N₄) film. Additionally, since the low-k material is brittle, during a dicing process that separates a semiconductor wafer having semiconductor elements formed thereon into individual semiconductor chips, a crack may occur and propagate through a film interface between the low-k film and another dielectric film. The crack may reach an element formation region of the semiconductor device, which may result in a lower yield of semiconductor devices.

### BRIEF DESCRIPTION OF THE DRAWINGS

FIG. 1 depicts a layout of a plurality of semiconductor chips in a semiconductor wafer at least partly in a plan view in accordance with an embodiment of the disclosure.

FIG. 2 depicts adjacent semiconductor chips in an enlarged plan view in accordance with an embodiment of the disclosure.

FIGS. 3A and 3B each depict a portion including a scribe region in a cross-sectional view in accordance with an embodiment of the present disclosure.

FIGS. 4A and 4B each depict part of a scribe region in a plan view in accordance with an embodiment of the present disclosure.

FIGS. 5A-5C depict processes of forming a portion including a scribe region in a cross-sectional view in accordance with an embodiment of the disclosure.

FIGS. 6A and 6B each depict a portion including a scribe region in a cross-sectional view in accordance with an embodiment of the present disclosure.

### DETAILED DESCRIPTION

Various example embodiments of the disclosure will be described below in detail with reference to the accompanying drawings. The following detailed descriptions refer to the accompanying drawings that show, by way of illustration, specific aspects in which embodiments of the disclosure may be practiced. These embodiments are described in sufficient detail to enable those skilled in the art to practice the disclosure. Other embodiments may be utilized, and structure, logical and electrical changes may be made without departing from the scope of the disclosure. The various embodiments disclosed herein are not necessary mutually exclusive, as some disclosed embodiments can be combined with one or more other disclosed embodiments to form new embodiments.

In the descriptions, common or related elements and elements that are substantially the same are denoted with the same signs, and the descriptions thereof may be reduced or omitted. In the drawings, the dimensions and dimensional ratios of each unit do not necessarily match the actual dimensions and dimensional ratios in the embodiments.

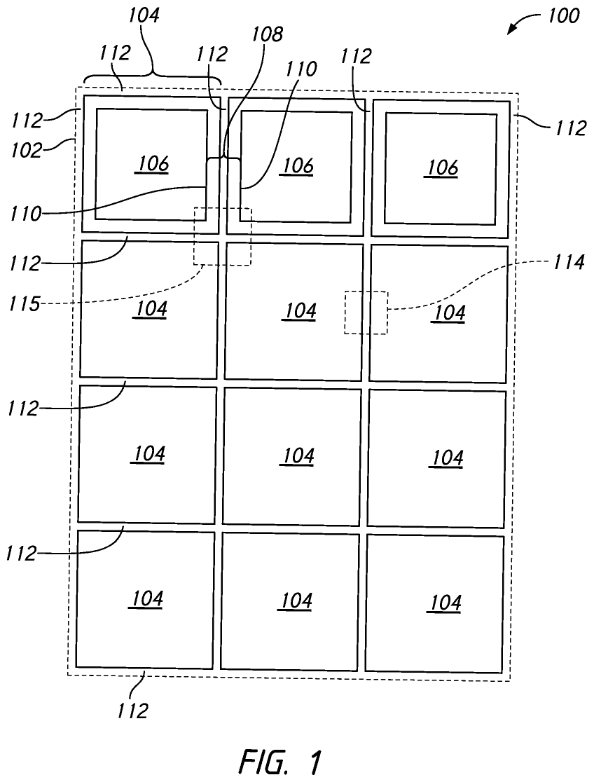

FIG. 1 depicts an example of a layout of a plurality of semiconductor chips 104 in a semiconductor wafer 100 at least partly in a plan view in accordance with an embodiment of the disclosure. The semiconductor wafer 100 includes a plurality of semiconductor chips 104. Each of the semiconductor chips 104 includes a circuit region 106. Each semiconductor chip 104 also includes one or more circuit edges 110 around the corresponding circuit region 106. The circuit regions 106 are provided in a matrix arrangement. Each circuit region 106 has a rectangular shape. In each circuit region 106, transistors and circuit components, including conductive interconnects, may be provided. The transistors and the circuit components may include a plurality of memory cells, one or more circuits that provide memory access functions, such as read operations and write operations to the memory cells, and a control circuit that controls the circuits.

Between the neighboring circuit regions 106 are scribe regions 108. Each scribe region 108 is provided around each circuit region 106. The scribe region 108 includes the circuit edges 110, facing one another in a plan view, of the adjacent or neighboring semiconductor chips 104. The scribe region 108 within each semiconductor chip 104 may include a test element group (TEG) (not separately depicted) including one or more test circuits. There may be provided a plurality of TEGs. The scribe region 108 may also include test terminals. The scribe region 108 may also include input/output terminals of the semiconductor chips 104. The scribe region 108 may also include various marks to be used for, for example, a photo process and a film thickness measurement process. Photo-lithography process marks may include, for example, an alignment mark and an overlay measurement mark. Each scribe region 108 includes a scribe center region 112 between the circuit edges 110 of the adjacent semiconductor chips 104.

A dicing line or a scribe cut line may be defined in the scribe center region 112 for separating the semiconductor wafer 100 into the individual semiconductor chips 104 by dicing. The dicing may be performed along the dicing line in the scribe center region 112. As one example, blade dicing may be performed. As another example, stealth dicing or stealth laser dicing may be performed. A more specific example may be the conventional stealth dicing before grinding (SDBG) technology or process. In the conventional SDBG process, laser is applied onto a back side of the semiconductor wafer 100 to generate cracks as a stealth dicing step, the back side of the semiconductor wafer 100 is grinded to be thinner by for example chemical-mechanical polishing (CMP) as a wafer back grinding step, and the semiconductor chips 104 are divided along the cracks by a die separation step.

The semiconductor wafer 100 includes portions 114 and 115. The portion 114 includes at least part of the adjacent semiconductor chips 104 and part of the scribe center region 112 between sides of the adjacent semiconductor chips 104. The portion 115 includes corners of the adjacent semiconductor chips 104 and part of the scribe center regions 112 between the corners of the adjacent semiconductor chips 104. The portion 115 includes corners of the circuit regions 106 and the scribe regions 108.

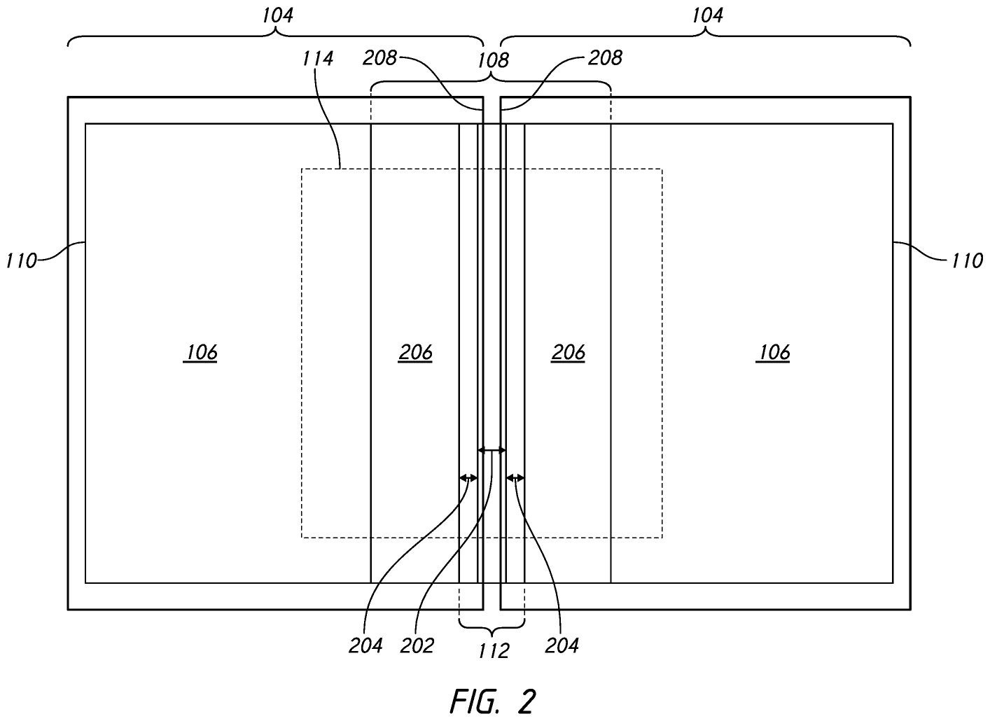

FIG. 2 depicts in an enlarged plan view an example of the adjacent semiconductor chips 104 in accordance with an embodiment of the disclosure. The adjacent semiconductor chips 104 include the scribe region 108 between the circuit regions 106. In the present embodiment, the scribe region 108 includes regions 206 adjacent to the circuit regions 106 of the semiconductor chips 104. The regions 206 are adjacent to or facing each other in the scribe region 108 in a plan view. In some instances, the regions 206 may include input/output terminals of the semiconductor chips 104. The regions 206 may also include one or more test circuits of one or more TEGs. The regions 206 may also include test terminals. In still some instances, the regions 206 may include pads for the TEGs. The pads may be configured to be used as electrodes (may also be referred to as pad electrodes) for measuring TEGs.

The scribe center region 112 is provided at the center or substantially the center of the scribe region 108. The scribe center region 112 runs along the adjacent sides of the adjacent regions 206 in a plan view. The scribe center region 112 may include the dicing line or the scribe cut line. The scribe center region 112 includes a crack guide region 202. The crack guide region 202 may include a crack guide structure at the center or substantially the center of the scribe center region 112. The crack guide structure in the crack guide region 202 may guide an excessive force or physical stress, which is exerted or caused due to dicing along the crack guide structure in the scribe center region 112, away from the semiconductor chips 104.

The crack guide region 202 may have a width greater than a width of a laser beam used in stealth dicing. In some instances, the crack guide structure in the crack guide region 202 may collapse to absorb an excessive force or physical stress due to dicing. After dicing, each semiconductor chip 104 has a side surface 208. Each semiconductor chip 104 may include a structure extending along the side surface 208. The structure extending along the side surface 208 may be a portion of the crack guide region 202. In some instances, cracks generated by the dicing process, such as the SDBG process, may extend along the side surface 208 of each semiconductor chip 104. In some instances, the structure along the side surface 208 may collapse.

The scribe center region 112 also includes crack mitigation regions 204 on sides of the crack guide region 202. The crack mitigation regions 204 may include crack mitigation structures. The crack mitigation structures in the crack mitigation regions 204 may help prevent the excessive force or physical stress caused by dicing from propagating to the neighboring semiconductor chips 104 and hence from generating cracks that reach the semiconductor chips 104. The crack mitigation structures in the crack mitigation regions 204 may be provided outside the regions 206. The crack mitigation structures outside the regions 206 may be apart from the test terminals in the regions 206.

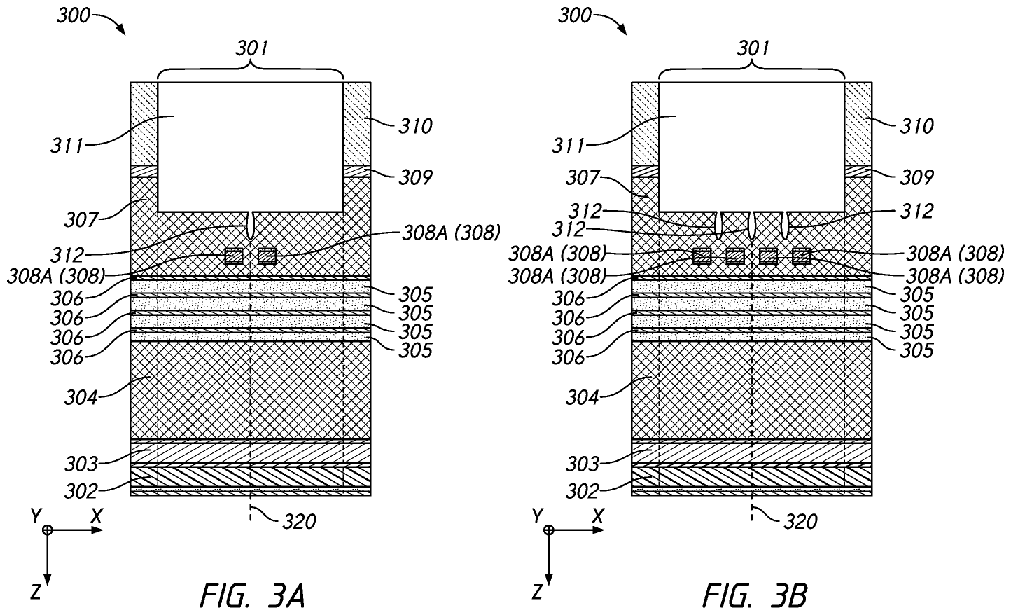

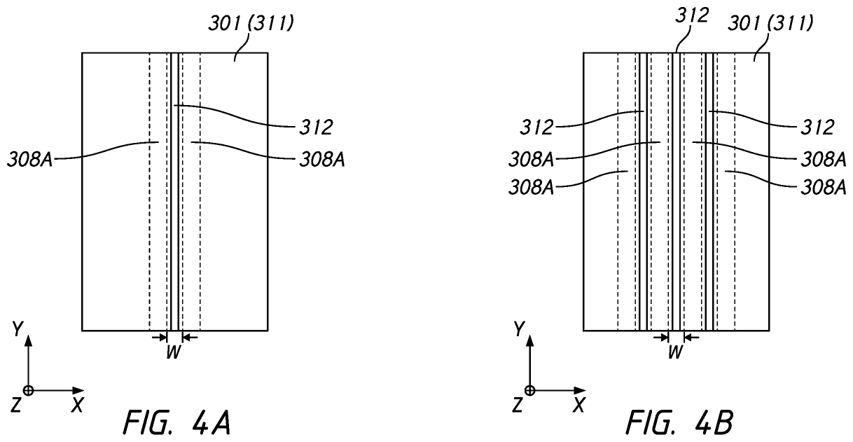

FIGS. 3A and 3B depict examples of a portion 300 including a scribe region 301 in a cross-sectional view in accordance with an embodiment of the disclosure. FIGS. 4A and 4B depict examples of part of the scribe region 301 in a plan view in accordance with an embodiment of the disclosure.

In some instances, the portion 300 may be included in the portion 114 of FIGS. 1 and 2, and the scribe region 301 may be included in the scribe region 108 of FIGS. 1 and 2. On both sides of the scribe region 301 may hence be regions corresponding to the circuit regions 106 of FIGS. 1 and 2. Although not separately depicted in FIGS. 3A and 3B, a scribe center region similar to the scribe center region 112 including the crack guide region 202 (which may further include the crack guide structure) and the crack mitigation regions 204 (which may further include the crack mitigation structures) of FIGS. 1 and 2 may be included in the scribe region 301. In other instances, the portion 300 and the scribe region 301 may not be included in the portion 114 and the scribe region 108, and may be included in other portions and/or regions.

The portion 300 includes a stack of multiple layers above a semiconductor substrate 302 in a vertical direction, which is Z-direction in the drawing. The layer stack includes, for example, an insulating layer 303, an insulating layer 304, insulating layers 305, barrier layers 306, an insulating structure 307, a top metal layer 308, a passivation layer 309, and a polyimide layer 310. Each layer extends in horizontal directions, which are X- and Y-directions in the drawing. In the drawing, X- and Y-directions are perpendicular to each other in a horizontal plane, and Z-direction is perpendicular to X- and Y-directions in a vertical plane. The stacked layers are not limited to the examples and the embodiments described herein. Other layers and/or other layer combinations are applicable as appropriate.

The portion 300 includes the scribe region 301. The scribe region 301 includes a groove 311 and an air gap 312. A scribe cut line or a dicing line 320 may be defined in the scribe region 301. For example, the scribe cut line 320 runs at a center or substantially the center of the scribe region 301 in the horizontal (X) direction and extends from the semiconductor substrate 302 toward the air gap 312 and the groove 311 in the vertical (Z) direction. The scribe cut line 320 indicates a position where dicing is to be performed in the scribe region 301.

The scribe region 301 may include a portion fabricated in a front-end-of-line (FEOL) above the semiconductor substrate 302. The FEOL includes, for example, memory cells (not separately depicted) on the semiconductor substrate 302 in a circuit region (for example, the circuit region 106 of FIG. 1). The insulating layer 303 is provided on the semiconductor substrate 302. The insulating layer 303 may include an insulating film. Another insulating layer 304 is provided on the insulating layer 303. The insulating layer 304 may include an insulating film. The insulating layer 304 may include dielectric material, such as silicon dioxide (SiO₂).

The scribe region 301 may include a portion fabricated in a back-end-of-line (BEOL) above the portion fabricated in the FEOL. The portion fabricated in the BEOL may include, for example, the insulating layers 305 and the barrier layers 306 stacked on one another above the insulating layer 304.

Each insulating layer 305 may include an insulating film. The insulating layers 305 may include a material having a lower dielectric constant (k) than SiO₂. The low-k material in the insulating layers 305 reduces parasitic capacitance between interconnects. Using the low-k material help to achieve high-speed operations of electronic circuits in the semiconductor chips 104. The low-k material in the insulating layers 305 may include, for example, silicon oxycarbide/carbon-doped silicon oxide (SiOC) and porous SiOC.

Each barrier layer 306 may include a barrier film. The barrier layers 306 prevent diffusion of a conductive material. The barrier layers 306 may include so-called barrier low-k (BLOK) films to prevent diffusion of a conductive material, such as Cu. The BLOK films may include a material having a lower k than silicon nitride (Si₃N₄). The low-k material in the barrier layers 306 may include, for example, SiCN. At least one of the barrier layers 306 may include Si₃N₄ to improve adherence of the conductive material regardless of the dielectric constant (k). At least one of the barrier layers 306 may include transition metal or transition metal nitride. The transition metal may be, for example, yttrium (Y), titanium (Ti), zirconium (Zr), hafnium (Hf), niobium (Nb), or tantalum (Ta). At least one of the barrier layers 306 may include alumina or aluminum oxide (Al₂O₃).

While the scribe region 301 includes the stack of the insulating layers 305 and barrier layers 306, the number and the location of the insulating layers 305 as well as the number and the location of the barrier layers 306 included in the BEOL are not limited to the examples and the embodiments described herein. Any number and location are applicable as appropriate.

The insulating structure 307 is provided above a top layer of the stacked insulating layers 305, or more specifically, on an upper surface of the barrier layer 306 that covers the top insulating layer 305. The insulating structure 307 may include an insulating layer. The insulating layer may include an oxide film. The insulating layer may include SiO₂.

In the insulating structure 307, the top metal layer 308 is provided. The top metal layer 308 is embedded in the insulating structure 307. The top metal layer 308 includes a plurality of metal wirings 308A arranged within the scribe region 301 of the portion 300. The metal wirings 308A may also be referred to as wiring lines or simply lines. The metal wirings 308A are arranged next to each other in the horizontal (X) direction with an area or a space therebetween. The metal wirings 308A run in the horizontal (Y) direction in the scribe region 301. The number and the location of the metal wirings 308A are not limited to the examples and the embodiments described herein. Any number and location are applicable as appropriate. The metal wirings 308A may include a metal material, such as aluminum (Al).

Metal layers (not separately depicted) may be provided in the corresponding insulating layers 305 and form a stack of the metal layers in the portion 300 or the scribe region 301. The top metal layer 308 may be a top layer of the stacked metal layers. The respective metal layers may be referred to as M1, M2, M3, and so on counting from the bottom metal layer to the top metal layer in the vertical (Z) direction.

The passivation layer 309 is provided on the insulating structure 307. The passivation layer 309 may include a passivation film. The passivation film may be a nitride film. The passivation layer 309 may include silicon nitride (Si₃N₄). An upper surface of the insulating structure 307 outside the scribe region 301 is covered by the passivation layer (or the passivation film) 309.

The polyimide layer 310 is provided as a mask above the passivation layer 309. The polyimide layer 310 may include a photopolymer material.

The groove 311 is provided on the insulating structure 307 in the scribe region 301. The groove 311 penetrates through the polyimide layer 310 and the passivation layer 309 and reach partway in the insulating structure 307 in the vertical (Z) direction. At a bottom portion or a bottom surface of the groove 311, at least part of the insulating structure 307 in the scribe region 301 is exposed to an opening of the groove 311. The opening may be created in the scribe region 301 by conventional photo and etching techniques, such as photo lithography and dry etching, through the polyimide layer 310 and the passivation layer 309 and partway in the insulating structure 307. The thus-created opening forms the groove 311. In some instances, for example, the regions 206 of FIG. 2 may be provided at the bottom portion of the groove 311 between adjacent chips or dies (for example, the semiconductor chips 104). The groove 311 extends or runs along the scribe region 301 in the horizontal (Y) direction in a plan view or when viewed from the above of the portion 300. A width of the groove 311 in the horizontal (X) direction may be the same or substantially the same as that of the scribe region 301. The polyimide layer 310 provided in the regions, such as the circuit regions 106, next to the scribe region 301 (or the scribe region 108) may also be used as a mask for forming openings of pad electrodes by photo and etching techniques.

Provided between the groove 311 and the top metal layer 308 of the insulating structure 307 in the scribe region 301 is the air gap 312. The air gap 312 may be a void in the insulating layer 307. The air gap 312 has a horizontal (X-directional) cross-sectional shape that extends toward and reaches the groove 301 in the vertical (Z) direction. The air gap 312 extends or runs along the groove 311 in the horizontal (Y) direction in a plan view. The air gap 312 has its bottom portion or at least a bottom tip above or higher than an upper surface of the top metal layer 308 in the vertical (Z) direction. The air gap 312 is exposed at the groove 311. For example, a top portion or at least a top tip of the air gap 312 is exposed at the bottom portion or the bottom surface of the groove 311. The entirety of the air gap 312 is above the area between the neighboring metal wirings 308A of the top metal layer 308. The entirety of the air gap 312 is embedded in the structure 307 except for the exposed top portion at the bottom portion of the groove 311. In the case where the scribe cut line 320 is defined at a center or substantially the center of the scribe region 301 in the horizontal (X) direction, for example, at least part of the area between the neighboring metal wirings 308A is on the scribe cut line 320 or at a position vertically straight from the scribe cut line 320, and the air gap 312 is also at a similar position with respect to the scribe cut line 320. The air gap 312 is thus positioned corresponding to the scribe cut line 320, which indicates the position where dicing is to be performed, within the scribe region 301.

In some instances, a plurality of air gaps 312 are provided in the insulating structure 307. The plurality of air gaps 312 are arranged next to each other in the horizontal (X) direction. Each of the air gap 312 extends toward the bottom portion of the groove 311 in the vertical (Z) direction. Each of the air gaps 312 has its bottom portion or at least its bottom tip above or higher than the upper surface of the top metal layer 308 in the vertical (Z) direction. Each of the air gaps 312 has its top portion or at least its top tip exposed at the bottom portion or the bottom surface of the groove 311. The entirety of each air gap 312 is above the area between the neighboring metal wirings 308A of the top metal layer 308. In the case where the top metal layer 308 includes more than three metal wirings 308A arranged next to each other in the horizontal (X) direction within the scribe region 301, each of the air gaps 312 is arranged at a position corresponding to and above each of the areas between the neighboring metal wirings 308A. In the case where the scribe cut line 320 is defined at a center or substantially the center of the scribe region 301 in the horizontal (X) direction, for example, at least one of the air gaps 312 in the middle is provided at a position corresponding to the scribe cut line 320.

The number of the air gaps 312 is not limited to the examples illustrated in FIGS. 3A-3B and 4A-4B. For example, only one air gap 312 may be provided at a position above or higher than one of the areas between the neighboring metal wirings 308A among the plurality of metal wirings 308A. Such an area may be the one at a position corresponding to the scribe cut line 320 in the scribe region 301.

The area between the neighboring metal wirings 308A may have a sufficient width for the air gap 312 to be positioned between the neighboring metal wirings 308A in a plan view or when viewed from above as illustrated in FIGS. 4A-4B. The width W of the space between the neighboring metal wirings 308A, or more specifically between the facing side walls of the neighboring metal wirings 308A, in the horizontal (X) direction may be, for example, between 1.5 um (micro meter) and 3.0 um or between about 1.5 um and about 3.0 um. The height of the air gap 312 may depend on the width W of the space. In some instances, for example, at least within the range of 1.5-3.0 um, the wider the width W is, the greater the air gap height is.

According to the present embodiment, at least part of the scribe region 301 of the portion 300 which includes the air gap (or air gaps) 312 is structurally weaker than areas or regions outside the scribe region 301. During dicing, such as SDBG to perform dicing from the backside of a wafer, that is the semiconductor substrate 302 in the example, along the scribe region 301, the structure of the present embodiment guides a crack or cracks generated by the dicing to run in the structurally weaker part of the scribe region 301 toward the air gap 312 and then the groove 311. A force or physical stress due to dicing may propagate easier in the scribe region 301 than areas outside the scribe region 301. The crack is thus likely to extend along the scribe region 301 or the scribe cut line 320 and less likely to spread sideways, that is in the chip or die direction. Consequently, the dicing along the scribe region 301 can be effectively facilitated, improving the yield of non-defective chips/dies or devices.

In the present embodiment, the air gap (or air gaps) 312 may be provided in a region similar to the scribe center region 112 of FIGS. 1 and 2 in the scribe region 301. The air gap 312 may be provided in the crack guide region 202 (FIG. 2). The air gap 312 may be part of the crack guide structure. Alternatively or additionally, the air gap 312 may be provided in the crack mitigation regions 204 (FIG. 2). The air gap 312 may be part of the crack mitigation structures. Such configurations even further effectively facilitate the formation of the individual chips/dies by dicing with less force and cracks reaching the adjacent chips/dies, such as the semiconductor chips 104.

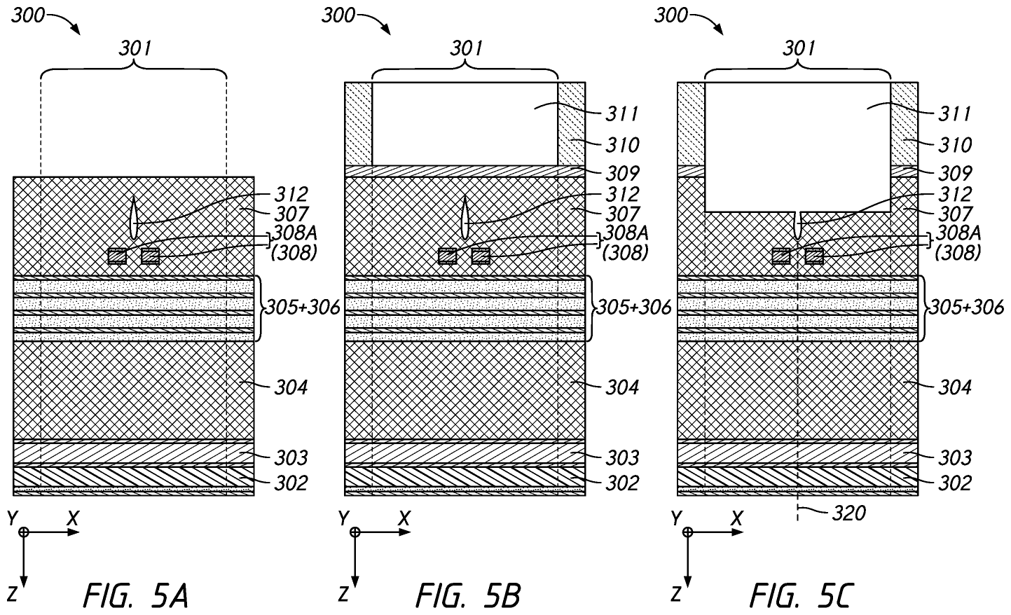

FIGS. 5A-5C depict an example of processes of forming the portion 300 including the scribe region 301 in a cross-sectional view in accordance with an embodiment. The example mainly illustrate the formation of the air gap 312 and the groove 311 in the scribe region 301.

Prior to the formation of the air gap 312, the various layers including the insulating layers 303, 304 and 305 and the barrier layers 306 are formed on top of each other above the semiconductor substrate 302 by conventional methods. Examples of the conventional methods include, but are not limited to, single damascene, dual damascene, physical vapor deposition (PVD), plating, photo-lithography, dry etching, chemical-mechanical polishing (CMP), and a combination thereof. Any conventional materials may be used for the respective layers by the conventional methods as appropriate. These layers may be elements of a semiconductor device, such as a memory device. A memory device may include a dynamic random access memory (DRAM).

On the insulating and barrier layer stack, the insulating structure 307 including the top metal layer 308 and the air gap 312 is formed (FIG. 5A). More specifically, as one example, a first plasma oxide film as a lower portion of the insulating structure 307 is first formed on the barrier layer 306. The top metal layer 308 including the metal wirings 308A is formed in the first plasma oxide film by conventional photo and etching techniques. A second plasma oxide film as an upper portion of the insulating structure 307 is formed to cover the metal wirings 308A. During the formation of the second plasma oxide film, the air gap 312 is formed. For example, conditions of forming the second plasma oxide film are adjusted such that the air gap 312 with the intended shape at the intended position according to the present embodiment is formed. As one example, a SiO₂ film with less step coverage than a film formed by thermal CVD may be formed as the second plasma oxide film of the insulating structure 307 to provide the air gap 312. Such SiO₂ film including the air gap 312 may be formed by, for example, plasma-enhanced CVD (PECVD) and CMP processes. The PECVD may use appropriate source gases, such as silane (SiH₄) and dinitrogen monoxide (N₂O), at predetermined pressure, temperature, high and low frequency power, and the like. The air gap 312 according to the present embodiment is, for example, to be located at the position above the area between the neighboring metal wirings 308A and to have the shape reaching the groove 311 and including the bottom portion thereof located higher than the upper surface of the metal wirings 308A or the top metal layer 308 and the top portion thereof exposed at the groove 311.

Subsequently, the passivation layer 309 and the polyimide layer 310 are formed on an upper surface of the insulating structure 307, and the opening which provides the groove 311 in the scribe region 301 is formed through the polyimide layer 310 by the conventional photo technique (FIG. 5B) and further through the passivation layer 309 into the insulating structure 307 by the conventional dry etching technique (FIG. 5C). The opening penetrates partway the insulating structure 307. The dry etching forms the opening or the groove 311 such that the bottom portion thereof reaches the top portion of the air gap 312 in the insulating structure 307. The air gap 312 is thus exposed at the groove 311.

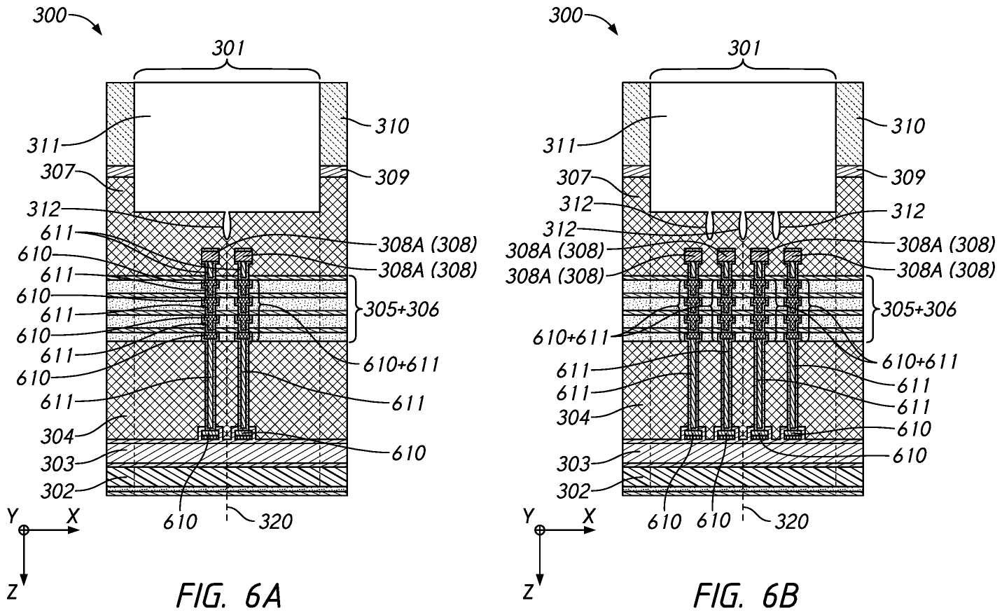

FIGS. 6A and 6B depict other examples of the portion 300 including the scribe region 301 in a cross-sectional view in accordance with an embodiment of the disclosure. In these examples, metal wirings 610 and vias 611 are further provided below the top metal layer 308 in the scribe region 301. The metal wirings 610 are formed in the respective insulating layers 305 and 304. The vias 611, such as conductive vias, are formed to electrically couple the metal wirings 610 as well as the metal wirings 308A with one another in the respective layers. The metal wirings 610 and the vias 611 are aligned with one another and also with the metal wirings 308A in the vertical (Z) direction. The metal wirings 610 and the vias 611 are arranged on both sides, which are left and right sides in the horizontal (X) direction in the drawing, of the scribe cut line 320 defined in the scribe region 301. These metal wirings 610 and the vias 611 form a pair of vertical or substantially vertical (sub-)groups on both sides of the scribe cut line 320 in the scribe region 301. The metal wirings 610 and the vias 611 may be arranged only on one side of the scribe cut line 320. The metal wirings 610 and the vias 611 can be formed by conventional methods, such as photo lithography and dry etching techniques, using conventional metal or conductive materials, as appropriate. As to a size of each element, for example, each metal wiring 610 may have a width of about 300 nm in the horizontal (X) direction, and each via 611 may have a width less than that of the metal wiring 610.

According to the present embodiment, the pair of the groups of the metal wirings 610 and the vias 611 work like walls along the scribe cut line 320 to prevent a crack generated by dicing from spreading sideways or away from the scribe cut line 320, and such a crack is further less likely to reach the chips or dies. Together with the air gap 312, this configuration even further facilitates the wafer dicing, reduces defective chips/dies or devices caused by dicing, and improves the yield thereof.

Although various embodiments of the disclosure have been described in detail, it will be understood by those skilled in the art that embodiments of the disclosure may extend beyond the specifically described embodiments to other alternative embodiments and/or uses and modifications and equivalents thereof. In addition, other modifications which are within the scope of the disclosure will be readily apparent to those of skill in the art based on the described embodiments. It is also contemplated that various combination or sub-combination of the specific features and aspects of the embodiments may be made and still fall within the scope of the disclosure. It should be understood that various features and aspects of the embodiments can be combined with or substituted for one another in order to form varying mode of the embodiments. Thus, it is intended that the scope of the disclosure should not be limited by the particular embodiments described above.

What is claimed is:

1. An apparatus, comprising:
an insulating structure in a scribe region;
a plurality of metal layers, the metal layers including a top metal layer in the insulating structure in the scribe region;
a groove on the insulating structure in the scribe region; and
an air gap between the top metal layer and the groove in the scribe region.

2. The apparatus according to claim 1, wherein a bottom portion of the air gap is higher than an upper surface of the top metal layer.

3. The apparatus according to claim 1, wherein the air gap is exposed at the groove.

4. The apparatus according to claim 1, wherein the air gap includes a top portion exposed at a bottom portion of the groove.

5. The apparatus according to claim 1, wherein the groove penetrates partway the insulating structure.

6. The apparatus according to claim 1, wherein
the top metal layer includes a plurality of metal wirings in the scribe region, and
the air gap is above an area between neighboring metal wirings among the plurality of metal wirings.

7. The apparatus according to claim 1, wherein
the air gap includes a plurality of air gaps arranged next to each other,
each of the plurality of air gaps is between the top metal layer and the groove, and
a bottom portion of each of the plurality of air gaps is higher than an upper surface of the top metal layer.

8. The apparatus according to claim 7, wherein
the top metal layer includes a plurality of metal wirings in the scribe region,
the plurality of metal wirings are arranged next to each other, and
each of the plurality of air gaps is above an area between neighboring metal wirings among the plurality of metal wirings.

9. The apparatus according to claim 1, further comprising:
a plurality of insulating layers under the insulating structure;
a plurality of metal wirings in the respective insulating layers; and
a plurality of vias configured to electrically couple the metal wirings with one another, wherein
the metal wirings and the vias are aligned with one another in a vertical direction, and
both the metal wirings and the vias are on one side or both sides of a scribe cut line in a horizontal direction in the scribe region.

10. The apparatus according to claim 9, wherein
the metal wirings and the vias form a pair of groups of the metal wirings and the vias, and
the pair of groups of the metal wirings and the vias are on the respective sides of the scribe cut line.

11. An apparatus, comprising:
an insulating structure in a scribe region;
a plurality of metal layers, the metal layers including a top metal layer in the insulating structure in the scribe region;
a groove on the insulating structure in the scribe region; and
an air gap between the top metal layer and the groove in the scribe region, the air gap including a top portion exposed at a bottom portion of the groove and a bottom portion above an upper surface of the top metal layer.

12. The apparatus according to claim 11, wherein
the scribe region extends in a first direction,
the groove extends along the scribe region in the first direction and penetrates partway the insulating structure in a second direction perpendicular to the first direction,
the air gap extends along the scribe region in the first direction and reaches the groove in the second direction in the insulating structure.

13. The apparatus according to claim 11, wherein the air gap is provided in the scribe region corresponding to a position where dicing is to be performed.

14. The apparatus according to claim 11, wherein the groove penetrates partway the insulating structure.

15. The apparatus according to claim 11, wherein
the top metal layer includes a plurality of metal wirings in the scribe region, and
the air gap is above an area between neighboring metal wirings among the plurality of metal wirings.

16. The apparatus according to claim 11, wherein
the air gap includes a plurality of air gaps arranged next to each other, and
each of the plurality of air gaps includes the top portion exposed at the bottom portion of the groove and the bottom portion above the upper surface of the top metal layer.

17. The apparatus according to claim 11, further comprising:
a plurality of insulating layers under the insulating structure;
a plurality of metal wirings in the respective insulating layers; and
a plurality of vias configured to electrically couple the metal wirings with one another, wherein
the metal wirings and the vias are aligned with one another in a vertical direction, and
both the metal wirings and the vias are on one side or both sides of a scribe cut line in a horizontal direction in the scribe region.

18. An apparatus, comprising:
an insulating structure in a scribe region;
a plurality of insulating layers under the insulating structure;
a plurality of metal layers including metal wirings in the respective insulating layers in the scribe region, the metal layers including a top metal layer in the insulating structure in the scribe region;
a plurality of vias configured to electrically couple the metal wirings with one another;
a groove on the insulating structure in the scribe region; and
an air gap between the top metal layer and the groove in the insulating structure in the scribe region, the air gap including a bottom portion higher than an upper surface of the top metal layer.

19. The apparatus according to claim 18, wherein the metal wirings and the vias are aligned with one another in the vertical direction and are on one side or both sides of a scribe cut line in a horizontal direction in the scribe region.

20. The apparatus according to claim 18, wherein
the top metal layer includes one or more metal wirings arranged neighboring to each other in the horizontal direction,
the air gap is above an area between the neighboring metal wirings, and
the air gap is exposed at the groove.
